(19) United States
(12) Patent Application Publication
(10) Pub. No.: US 2004/0026775 A1
(43) Pub. Date: Feb. 12, 2004

(54) Method for protecting electronic or micromechanical components

(76) Inventors: Hans Hecht, Korntal-Muenchingen (DE); Lutz Mueller, Aichtal (DE); Andreas Stark, Lauscha (DE); Werner Steiner, Boeblingen (DE)

Correspondence Address: KENYON & KENYON, ONE BROADWAY, NEW YORK, NY, 10004, US

(21) Appl. No.: 10/399,253

(22) PCT Filed: Oct. 2, 2001
(86) PCT No.: PCT/DE01/03785

(30) Foreign Application Priority Data
Oct. 14, 2000 (DE) 10051053.1

(51) Int. Cl. H01L 23/053; H01L 23/12

(52) U.S. Cl. 257/701

(57) ABSTRACT

A method of protecting electronic or micromechanical components having at least one contact face for electric contacting is described. Sensitive components such as electronic microchips having bond pads, for example, are protected from soiling and corrosion. This method includes the application of an organic protective layer at least to the contact faces of the components.

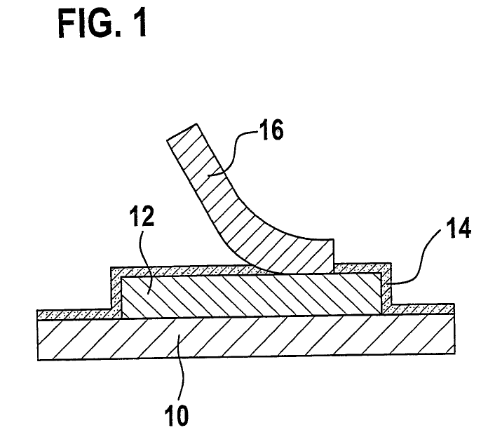

### FIELD OF THE INVENTION

The present invention relates to a method for protecting electronic or micromechanical components from soiling and/or corrosion as well as a component provided with a protective layer and use thereof.

### BACKGROUND INFORMATION

During the manufacture of electronic or micromechanical components, there is a need for methods for protecting the surface of such a component at least partially from soiling. For example, microchips are produced as interconnected components, which must then be separated by a mechanical procedure, namely sawing in the simplest case. The dust and sludge thus generated cause soiling of the contact faces of the microchips, for example, and must be removed. In the case of rugged components, this may be accomplished by a high-pressure cleaning, but this is impossible in the case of sensitive electronic or micromechanical components because of the possibility of damage.

### SUMMARY OF THE INVENTION

An object of the present invention is to provide a method which will ensure the protection of contact faces in particular of electronic or micromechanical components from soiling and/or corrosion.

The method according to the present invention has the advantage that it effectively ensures protection of even sensitive electronic or micromechanical components from soiling and/or corrosion. This is accomplished by applying an organic protective layer at least to the contact faces of the component.

The components are thus contacted in such a way as to eliminate any previous removing the protective layer, and the component is still protected from corrosion both during and after its manufacture. The protective layer is punctured during contacting.

In an especially advantageous embodiment of the method according to the present invention, a component for producing the protective layer is added to the cooling water used during the sawing operation, so that application of the protective layer may be integrated into the operation of separating the components.

### BRIEF DESCRIPTION OF THE DRAWING

An exemplary embodiment of the present invention is illustrated schematically in the single FIGURE and is explained in greater detail in the following description.

### DETAILED DESCRIPTION

The FIGURE illustrates schematically an electronic or micromechanical component having a contact face 12 for electric contacting of the component on a substrate 10 made of silicon, for example. Such a contact face is also known as a bond pad. It may contain aluminum, an aluminum/copper alloy, nickel, silver, a silver/palladium alloy, copper, or gold.

Electronic or micromechanical components are usually produced as interconnected components which are separated by mechanical means, usually by sawing, toward the end of production. In doing so, sawing sludge is deposited on the components, where it adheres very firmly and prevents subsequent reliable contacting of the components. In the case of rugged components, sawing sludge may be removed by a high-pressure cleaning after separation of the components, but this is impossible with sensitive components.

Therefore, before separation, at least contact faces 12 of the component are provided with an organic protective layer 14, and the remaining surface of the component may also be coated with protective layer 14 entirely or partially, depending on the application. In addition to protection from soiling, protective layer 14 also helps to prevent corrosion of the component.

In contacting, contact face 12 of the component is provided with an electric conductor 16, electric conductor 16 being applied to the surface of contact face 12 in such a way that it punctures protective layer 14. Essentially all conventional welding and soldering methods are suitable, but ultrasonic welding has proven to be especially favorable with regard to the least possible damage to protective layer 14. As an alternative, it is quite possible to remove protective layer 14 between the separation and contacting. This procedure will depend on the specific individual case.

Before applying organic protective layer 14 to the contact face, i.e., the surface of the component, a surface treatment of the component is performed, for example. In doing so, the component is degreased and, if necessary, etched by using an aqueous solution which may contain hydrogen peroxide and/or alkaline constituents to obtain a reactive surface having terminal OH groups.

Thin, well-adhering layers or lacquers are suitable as protective layer 14, containing polysilanes, polysiloxanes, polyglycols, or polyetherglycols, for example. It is also conceivable to apply waxes or oils. It is especially advantageous to use fluorine-substituted compounds, which form a hydrophobic surface and facilitate contacting of the component. For example, if aluminum wire is used as electric conductor 16, then aluminum fluoride is formed during contacting and functions as a soldering flux agent, greatly increasing the strength of the point of contact.

Suitable methods of applying protective coating 14 include spin coating, spraying, immersion, lacquering, a drip process, and screen printing. Methods such as CVD in which the compounds are vapor deposited under a reduced pressure are also suitable. This is also true of plasma-enhanced deposition, sputtering, and PVD.

Organotrialkoxysilanes or organotrichlorosilanes, which react well with both silicon surfaces and aluminum surfaces, are especially suitable. Two exemplary embodiments are described below.

1^{st} Exemplary Embodiment:

The surface of a silicon wafer 10 having at least one aluminum contact point 12 is exposed to gaseous hexamethyldisilazane for five minutes in a vacuum oven at approx. 150° C. and approx. 10 mbar. The surface is then hydrophobic. purpurins 2^{nd} Exemplary Embodiment:

A 0.5% solution of 1,1,2,2-tetrahydroperfluoro-octyltriethoxysilane in 2-propanol is applied to the surface of a silicon wafer 10 having at least one aluminum contact point 12, and after a waiting time of ten minutes, the solution is spun off at approx. 4000 rpm for 30 seconds in a spin coater. The wafer is then heated for ten minutes at approx. 120° C. Protective layer 14 produced in this way permits contacting of the component with a 50 μm thick aluminum wire, for example, so that due to the formation of aluminum fluoride during the contacting operation, the contacting stability is greater than that with components without the protective layer.

It is especially advantageous if creation of protective layer 14 is integrated into the separation process because this makes it possible to eliminate one processing step. In this case, the compounds for forming the protective layer are added to the rinsing and cooling water used with the water saw, for example. The water-soluble compounds immediately form a protective layer 14 on the wetted surface of the component, protecting the component from adhering sludge. As an alternative, the protective layer may also be applied by an aqueous immersion bath.

Suitable compounds for this include the monoesters and diesters of phosphoric or phosphonic acid, the partially fluorinated derivatives being especially suitable. A third exemplary embodiment is described below.

3^{rd} Exemplary Embodiment:

A silicon wafer having aluminum contact points 12 is immersed in a 0.1% aqueous solution of 1,1,2,2-tetrahydroperfluorohexyl phosphonic acid or 1,1,2,2-tetrahydroperfluoro-octyl phosphonic acid containing 5% 2-propanol, and after a dwell time of ten minutes the wafer is removed and rinsed off. Then the wafer is heated at approx. 120° C. for ten minutes.

The present invention is not limited to the exemplary embodiments described here, but instead it is also conceivable to include other fields of applications, which presuppose effective protection from impurities or corrosion, in addition to combining several of the methods described here for applying organic protective layer 14. This makes it possible to provide such a protective layer on very rugged articles made of metal.

What is claimed is:

1. A method of protecting electronic or micromechanical components from soiling and/or corrosion, preferably when separating the interconnected components the electronic or micromechanical components having at least one contact face for electric contacting, in particular of electronic microchips having bond pads, and an organic protective layer (14) being applied at least to the contact faces (12) of the components,
wherein the protective layer (14) contains silanes, siloxanes, polysiloxanes, their fluorinated derivatives, and/or perfluoropolyether compounds as a protective component, or it contains a phosphonic acid, a phosphonate ester, a phosphorate ester, and/or their fluorinated derivatives as a protective component.

2. The method as recited in claim 1,
wherein the protective layer (14) is plated through when welding connecting wires (16) to the contact faces (12) of the components.

3. The method as recited in claim 1,
wherein the components are contacted after removal of the protective layer (14).

4. The method as recited in claim 1,
wherein the protective layer (14) is applied by spin coating, immersion, plasma-enhanced deposition, CVD, PVD, or sputtering.

5. The method as recited in claim 6 [sic],
wherein the protective layer (14) is produced by rinsing the interconnected components with a solution containing the protective component.

6. The method as recited in one of the preceding claims, wherein the components are degreased before applying the protective layer (14).

7. The method as recited in one of the preceding claims, wherein before applying the protective layer (14), chemical activation of the contact face (12) is carried out by rinsing it with an alkaline solution and/or a solution containing hydrogen peroxide.

8. The method as recited in one of the preceding claims, wherein the interconnected components are separated in a mechanical manner, in particular by sawing.

9. The method as recited in one of the preceding claims, wherein the components are contacted by ultrasonic action.

10. An electronic or micromechanical component comprising at least one contact face for contacting the component, in particular an electronic microchip having bond pads, the contact face (12) having an organic protective layer (14), wherein the protective layer (14) contains silanes, siloxanes, polysiloxanes, their fluorinated derivatives, and/or perfluoropolyether compounds as a protective component, or it contains a phosphonic acid, a phosphonate ester, a phosphorate ester, and/or their fluorinated derivatives as a protective component.

11. The component as recited in claim 10,
wherein the protective layer (14) can be through-plated by connecting wires (16).

12. The component as recited in one of claims 10 through 11, wherein the component is produced by a method as recited in one of claims 1 through 11 [sic; 9].

13. Use of a component as recited in one of claims 10 through 12 to produce sensors, in particular air mass flow sensors.
